(19) United States
(12) Patent Application Publication
(10) Pub. No.: US 2026/0100691 A1
(43) Pub. Date: Apr. 9, 2026

(54) Multiple Cantilever MEMS Resonator

(71) Applicant: SiTime Corporation, Santa Clara, CA (US)

(72) Inventors: Ville Pekka Kaajakari, Helsinki (FI); Paul Merritt Hagelin, Saratoga, CA (US)

(21) Appl. No.: 19/354,829

(22) Filed: Oct. 9, 2025

Related U.S. Application Data
(60) Provisional application No. 63/705,492, filed on Oct. 9, 2024.

(51) Int. Cl. H03H 9/17; H03H 9/13; H03H 9/15

(52) U.S. Cl. CPC H03H 9/17; H03H 9/13; H03H 2009/155

(57) ABSTRACT

The present disclosure relates to micro-electromechanical systems (MEMS) resonators comprising multiple cantilevers. The MEMS resonator includes a substrate and a base, with at least two cantilevers coupled to the base. Each cantilever features a silicon layer, an insulating layer disposed on the silicon, and a piezoelectric layer selectively coupled to the silicon through openings in the insulating layer. Electrical terminals are provided via a first electrode on the piezoelectric layer and a second electrode on the substrate. +The design enables synchronized mechanical motion among the cantilevers, which may be actuated in-phase or out-of-phase to achieve balanced resonance and high quality factor. Additional features include trim masses for frequency adjustment, conductive layers for heating and connectivity, and packaging structures such as chip-scale and wafer-level packages with integrated getters and hermetic sealing.

### CROSS-REFERENCE TO RELATED APPLICATIONS

This application claims the benefit of U.S. Provisional Application No. 63/705,492, filed Oct. 9, 2024, which is incorporated by reference herein in its entirety.

### BACKGROUND

An oscillator may be a circuit that generates an oscillating electronic signal, typically a periodic waveform such as a sine wave or square wave. The output frequency of an oscillator may be controlled by a resonator. Oscillators are components in various electronic devices, for example, generating clock signals for digital systems.

### BRIEF DESCRIPTION OF THE DRAWINGS

The drawings illustrate embodiments of the present disclosure and are provided for the purposes of illustration and discussion of the principles and conceptual aspects of the technology. The embodiments depicted in the drawings are intended to illustrate, rather than limit, the scope of the disclosure. Similar or identical reference numbers are used to identify similar or identical elements in the various drawings and descriptions. In the accompanying drawings:

FIG. 1 shows a cantilever resonator, according to some embodiments.

FIGS. 2A-2D illustrate packaged resonators, according to various embodiments.

FIGS. 3A-3M depict cantilever resonators, in accordance with some embodiments.

FIGS. 4A and 4B present resonator packages, in accordance with various embodiments.

### DETAILED DESCRIPTION

While this technology is susceptible of embodiment in many different forms, there is shown in the drawings and will herein be described in detail several specific embodiments with the understanding that the present disclosure is to be considered as an exemplification of the principles of the technology and is not intended to limit the technology to the embodiments illustrated. Like or analogous elements and/or components, referred to herein, may be identified throughout the drawings with like reference characters.

It is understood that several of the figures are merely schematic representations of the present technology. As such, some of the components may have been distorted from their actual scale for pictorial clarity. Moreover, various combinations of the structures, components, materials, and/or elements, other than those specifically shown, are contemplated and are within the scope of the present technology. It is understood that non-stoichiometric forms of the compounds disclosed herein may be used.

The terminology used herein is for the purpose of describing particular embodiments only and is not intended to be limiting of the technology. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

As used herein, the phrase “A, B, and/or C” is intended to include any of the following combinations: only A, only B, only C, A and B, A and C, B and C, and A, B, and C. Similarly, the phrase “at least one of A, B, and C” is understood to encompass any of the following combinations: only A, only B, only C, A and B, A and C, B and C, and A, B, and C. In other words, combinations or subsets of the elements (e.g., A, B, and C) are included. Additionally, the expressions “A, B, and/or C” and “at least one of A, B, and C” may encompass permutations of the elements (e.g., A, B, and C). It is further understood that there may be any number of elements (e.g., A, B, C, and D; A, B, C, D, and E; etc.)

All patent applications, patents, and printed publications cited herein are incorporated herein by reference in the entireties, except for any definitions, subject matter disclaimers or disavowals, and except to the extent that the incorporated material is inconsistent with the express disclosure herein, in which case the language in this disclosure controls.

### Overview

The present technology may include a micro-electromechanical systems (MEMS) resonator including multiple cantilevers. As described herein, oxide, such as silicon dioxide (SiO₂) may selectively cover a top silicon surface. A piezoelectric material, such as aluminum nitride (AlN) may be selectively connected to the silicon surface where electromechanical transduction is desired.

Embodiments of the present technology may include two electrical terminals. A first terminal may be connected to an electrode on top of the piezoelectric material. A second terminal may be connected to structural silicon. The connection to the structural silicon may be through a conductive lid and/or substrate. An outside contact to the first terminal may be through a via in the conductive lid. An outside contact to the second terminal may be through the lid.

### Single Port

A common problem in MEMS resonators is that they usually require more than two electrical terminals. For example, a MEMS resonator may require an input terminal, output terminal, and ground terminal. For a small chip size (e.g., less than 500 μm in a lateral dimension), the number of connections to the chip is a limiting factor in assembling MEMS resonators with standard reflow soldering techniques. In other words, due to a minimum pad pitch the number of terminals in an area is limited. Embodiments of the present technology may advantageously eliminate the need for a third terminal by using the resonator body as the second terminal and incorporating a transducer(s) only in the desired location(s). It is understood that some embodiments may alternatively be dual port resonators.

### Parasitic Capacitance

By way of example and not limitation, the resonator may be formed of silicon on insulator (SOI) wafers. An SOI wafer may have a structural silicon layer that is typically 3-30 μm thick, insulating silicon dioxide layer that is typically 100-2000 nm thick, and silicon substrate that is 100-700 μm thick. There may also be a cavity that is formed in the substrate to enable large mechanical displacements (e.g., 5-20 μm). A common problem with these structures is that the capacitance between structural layer and substrate is large (e.g., 5-20 pF).

Embodiments of the present technology may advantageously have the structural layer and substrate electronically connected to eliminate this parasitic capacitance. The connection may be, for example, polysilicon that is deposited in a trench that goes through the structural layer and silicon dioxide layer. This polysilicon may advantageously encircle the resonator, such that the polysilicon forms a barrier against gas diffusion through the silicon dioxide layer. Moreover, further techniques may be applied to prevent incursion by small molecule gasses, such as hydrogen gas (H₂) and helium (He) gas. A barrier to block penetration of small molecules is discussed in U.S. Pat. No. 10,800,650 titled “MEMS with Small-Molecule Barricade,” the entirety of which is incorporated by reference herein.

### Insulating Layer

Some embodiments of the present technology may include an insulating layer on top of the structural silicon layer. This insulating layer may be, for example, silicon dioxide (SiO₂) or silicon nitride (Si₃N₄). The insulating layer may be patterned to expose the silicon surface, and a piezoelectric layer may be deposited to cover the patterned areas. The area of the piezoelectric layer may be selected to optimize transduction. The piezoelectric layer may be, for example, aluminum nitride (AlN) or zinc oxide (ZnO). A conductive actuator electrode may be deposited on top of the piezoelectric layer. The piezoelectric layer may be advantageously in contact with the structural silicon layer only in areas where piezoelectric transduction is desired, such as through the patterning of the insulating layer. In other areas, the insulating layer provides insulation between the actuator electrode and the structural silicon. The insulating layer is referred to as oxide 124A-124R in the accompanying figures.

### Terminals

In some embodiments, the resonator body, silicon substrate and conductive lid may be electrically connected together to form the first terminal, and the actuator electrode may be the second terminal. For example, the actuator electrode may be routed to the outside surface of the lid through a via in the lid so that electrode and the via have the same electrical potential.

A shunt capacitance between the first and the second terminal may be advantageously minimized. The capacitance may be mainly due to the actuator being formed by piezoelectric material on top of resonator body and the electrode above the piezoelectric material. In addition, there may be parasitic capacitance between the via and the lid. Furthermore, there may be signal routing from the lid to the actuator electrode. This routing may result in a small capacitance between the routing and the structural silicon. However, this capacitance may be minimized by the insulating layer (e.g., a layer of silicon dioxide) above the silicon.

In various embodiments, the first terminal contact may be made through the via in the lid, and the second terminal contact may be made through the conductive lid. Here, the conductive lid may make electrical contact with the structural silicon.

### Cantilevers

The resonating bodies may include multiple cantilevers. The cantilevers may be advantageously synchronized, such that the mechanical motion is balanced. For example, the resonator may include three cantilevers placed in parallel with the middle cantilever being actuated by piezoelectric transducers. The outer cantilevers may move out-of-phase with respect to the middle cantilever, thereby advantageously balancing the motion. Piezoelectric transducers may be fabricated on the outer cantilevers. Alternatively or additionally, the middle cantilever can excite a resonate mode of the structure, which may cause the outer cantilevers to move, even though only the middle cantilever is driven. In one-port embodiments, the one transducer may act as both a sense and drive electrode.

Each of the center cantilever and outer cantilevers may optionally include a trim mass. The trim mass(es) may be a mass(es) that can be removed to change the resonator's mass. The trim mass may be fabricated with metal, such as tungsten (W), molybdenum (Mo), gold (Au), and the like. The mass may be selectively removed using, laser trimming, ion beam trimming, and the like.

By way of example and not limitation, four cantilevers may be placed in parallel with two moving together and remaining two moving out phase with respect to the first two. It is understood that the techniques described herein may be applied to any number of cantilevers. For example, the resonator may include 1, 2, 5, 6, 7, 8, or more cantilevers.

### Cross Section

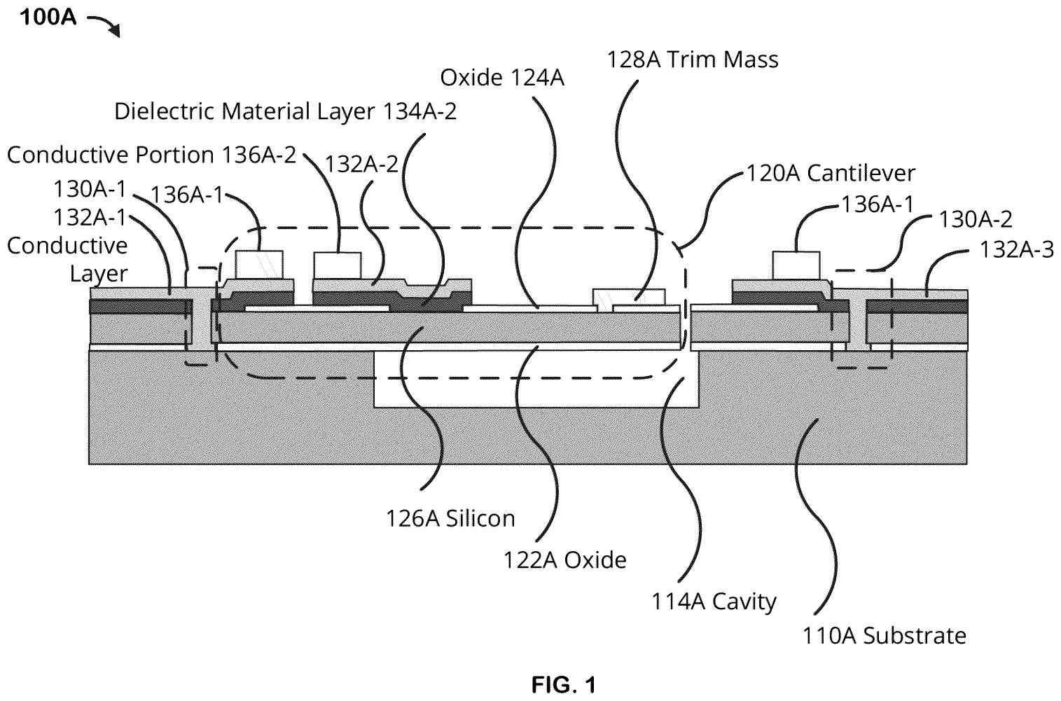

FIG. 1 depicts a cross sectional view of a resonator 100A, according to some embodiments. Resonator 100A may include substrate 110A, cavity 114A, oxide 122A, silicon 126A, cantilever 120A, conductive layer 132A-1 and 132A-3, connections 130A-1 and 130A-2, and conductive portion 136A-1. Cantilever 120A many include conductive portion 136A-2, conductive layer 132A-2, dielectric material layer 134A-2, and dielectric material layer 134A-2. By way of illustration and not limitation, conductive layer 132A-1-132A-3 may be in situ doped polysilicon (ISDP), dielectric material layer 134A-2 may be aluminum nitride (AlN), and silicon 126A may be single crystal silicon (SCS).

Conductive layer 132A-1-132A-3 may be a single crystal semiconductor, such as silicon. conductive layer 132A-1-132A-3 may be formed from at least one layer. For example, conductive layer 132A-1-132A-3 may include ISDP, a polycrystalline or amorphous form of silicon in which the doping impurities may be added during a deposition process to control the properties of the material. For example, group III (or p-type) dopants, which have one less valence electron than silicon, may create “holes” or areas of positive charge in the silicon crystal lattice, which makes it easier for the material to conduct positive charge carriers (holes) rather than negative charge carriers (electrons). P-type dopants may include boron (B), aluminum (Al), gallium (Ga), and indium (In). By way of further non-limiting example, group V (or n-type) dopants, which have one more valence electron than silicon, create extra or excess electrons in the silicon crystal lattice, which makes it easier for the material to conduct negative charge carriers (electrons) rather than positive charge carriers (holes). N-type dopants may include phosphorus (P), arsenic (As), antimony (Sb), and bismuth (Bi). Alternatively, doping of conductive material 1 (e.g., in CM1 410A) may occur after deposition. According to various embodiments, CM1 410A may be substantially silicon, which is at least 50% silicon by atomic weight.

Alternatively, conductive layer 132A-1 and 132A-3 may include metal (e.g., copper (Cu), aluminum (Al), molybdenum (Mo), gold (Au), platinum (Pt), titanium (Ti), tungsten (W), and the like), conductive ceramic (e.g., titanium nitride (TiN), tungsten carbide (WC), graphene, and the like), silicide (e.g., tungsten silicide (WSi₂), cobalt silicide (CoSi₂), titanium silicide (TiSi₂), nickel silicide (NiSi), platinum silicide (PtSi), and the like), other semiconductors (e.g., silicon carbide (SiC), gallium arsenide (GaAs), indium phosphide (InP), gallium nitride (GaN), and the like), and combinations/permutations thereof). The aforementioned materials may be doped as described above. Although shown as one layer, conductive layer 132A-1 and 132A-3 may include multiple layers composed of the materials described above.

Dielectric material layer 134A-2 may include aluminum nitride (AlN), a wide bandgap piezoelectric material with advantageous mechanical and thermal stability. Ideally, dielectric material layer 134A-2 may be a single crystal, such as a single crystal of AlN. A single crystal AlN resonator may have a high quality (Q) factor. Q factor may be a measure of the energy stored in the resonator per oscillation cycle, relative to the energy lost per cycle. A high-Q resonator may advantageously exhibit low energy dissipation and high energy storage, contributing to better performance.

Alternatively, dielectric material layer 134A-2 may include other dielectric materials having a crystalline structure, such scandium aluminum nitride (ScAlN), lithium tantalate (LiTaO₃), lithium niobate (LiNbO₃), lead zirconate titanate (PZT), and the like. Dielectric material layer 134A-2 may be a piezoelectric material. Piezoelectric materials may generate an electrical charge in response to mechanical stress or pressure, and conversely, produce a mechanical deformation or strain when subjected to an electrical field. Although shown as one layer, dielectric material layer 134A-2 may include multiple layers composed of the materials discussed above.

Silicon 126A may include SCS, a single-crystalline form of silicon that may have an advantageous mechanical quality factor and electrical properties. SCS may have a (100) crystal orientation (not depicted in FIG. 1). By way of further non-limiting example, SCS may have a (110) or (111) crystal orientations.

Alternatively, silicon 126A may include metal (e.g., copper (Cu), aluminum (Al), molybdenum (Mo), gold (Au), platinum (Pt), titanium (Ti), tungsten (W), and the like), conductive ceramic (e.g., titanium nitride (TiN), tungsten carbide (WC), graphene, and the like), silicide (e.g., tungsten silicide (WSi₂), cobalt silicide (CoSi₂), titanium silicide (TiSi₂), nickel silicide (NiSi), platinum silicide (PtSi), and the like), other semiconductors (e.g., silicon carbide (SiC), gallium arsenide (GaAs), indium phosphide (InP), gallium nitride (GaN), and the like), and combinations/permutations thereof). The aforementioned materials may be doped as described above for conductive layer 132A-1-132A-3. Although shown as one layer, silicon 126A may include multiple layers composed of the materials covered above.

As shown, there may be oxide 124A on top of structural silicon 126A. Optionally, there may be oxide 122A on the bottom (e.g., cavity 114A side) of structural silicon 126A, such as to balance stress from oxide on top 124A. Oxide 122A and 124A may be silicon dioxide (SiO₂), silicon nitride (Si₃N₄), and the like.

### Chip-Scale Package

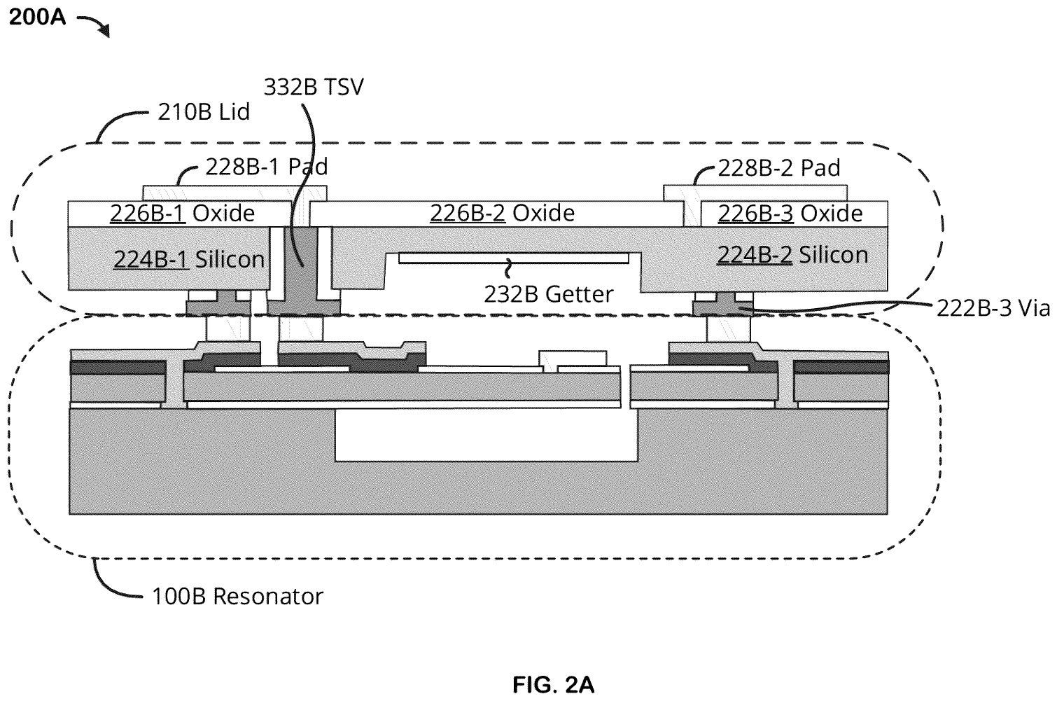

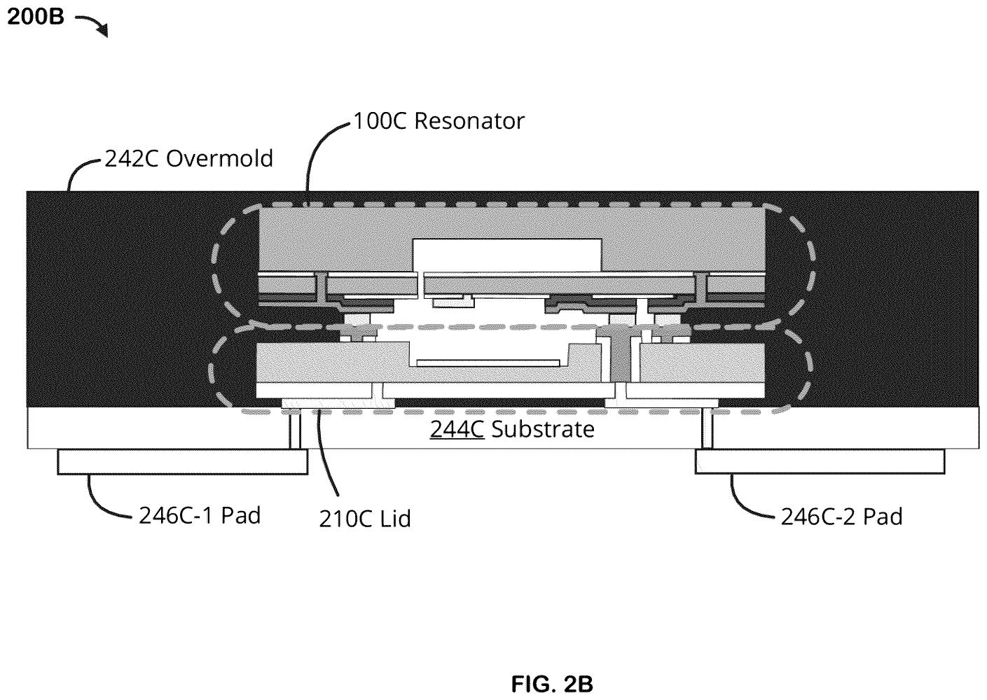

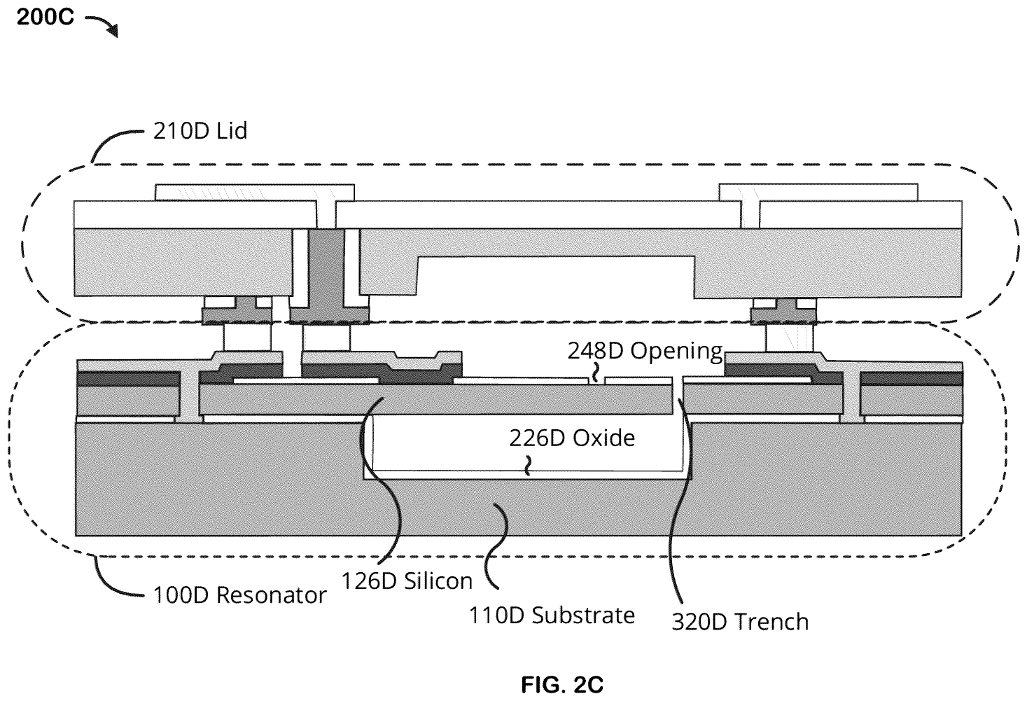

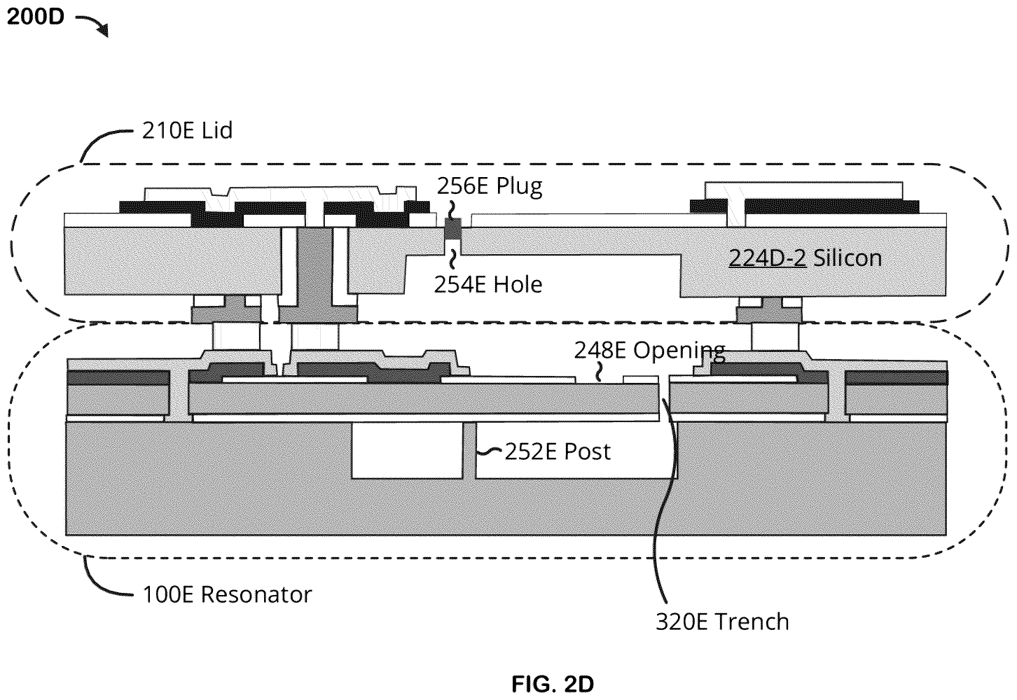

FIG. 2A shows a cross sectional view of a resonator in a chip-scale package (CSP) 200A, according to some embodiments. CSP 200A may include resonator 100B and lid 210B. Resonator 100B may incorporate one or more structural or functional features of resonator 100A described with reference to FIG. 1. Accordingly, unless otherwise specified, the description of resonator 100A is equally applicable to resonator 100B.

Lid 210B may include via 222B-3, silicon 224B-1 and 224B-2, oxide 226B-1-226B-3, pad 228B-1 and 228B-2, and getter 232B. Via 222B-3 may be a conductive structure that electrically connects different layers or regions within a semiconductor device. Via 222B-3 may include one or more conductive materials such as copper, tungsten, aluminum, gold, nickel, or silver-based epoxy, and may further comprise barrier or adhesion layers including titanium, titanium-tungsten, or chromium, selected based on desired electrical conductivity, thermal stability, and compatibility with semiconductor fabrication processes. Silicon 224B-1 and 224B-2 and oxide 226B-1-226B-3 may be structurally and/or functionally similar to silicon 126A and oxide 124A, respectively, described with reference to FIG. 1, and unless otherwise indicated, the description of silicon 126A and oxide 124A is considered applicable to silicon 224B-1 and 224B-2 and oxide 226B-1-226B-3, respectively.

Getter 232B may comprise a material disposed within the integrated circuit package that is configured to absorb or trap residual gases or moisture, and may include compounds such as titanium, zirconium, barium, or non-evaporable getter (NEG) alloys to maintain a controlled internal atmosphere and enhance device reliability. Pad 228B-1 and 228B-2 may be fabricated on top of oxide 226B-1-226B-2 and may include materials such as aluminum, copper, gold, nickel, or combinations thereof, selected for their electrical conductivity, adhesion properties.

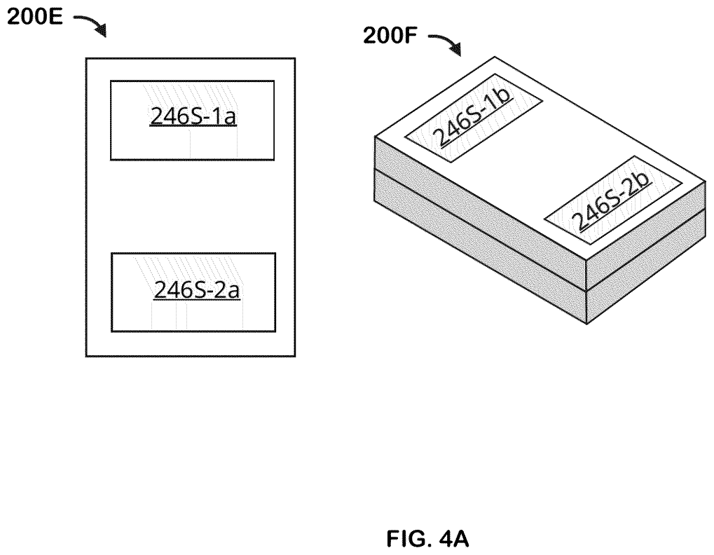

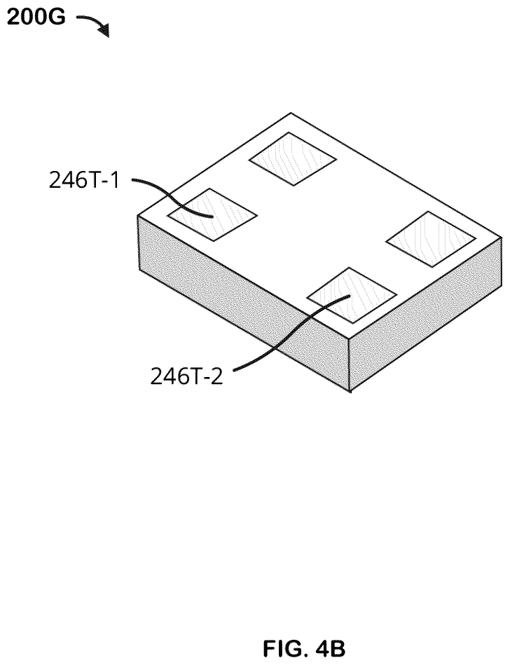

FIG. 4A illustrates a chip-scale package (CSP) 200E and 200F, according to various embodiments. CSP 200E may include pads 246S-1a and 246S-2a. CSP 200F may include pads 246S-1b and 246S-2b. Pads 246S-1a, 246S-2a, 246S-1b, and 246S-2b may may be structurally and/or functionally similar to pad 228B-1 and 228B-2 described with reference to FIG. 2A, and unless otherwise indicated, the description of pad 228B-1 and 228B-2 is considered applicable to pads 246S-1a, 246S-2a, 246S-1b, and 246S-2b. For example and not limitation, CSP 200E and 200F may have dimensions 0.4 mm×0.6 mm.

FIG. 2C shows a cross sectional view of a resonator in a chip-scale package (CSP) 200C, according to some embodiments. CSP 200C may include resonator 100D and lid 210D. Resonator 100D may incorporate one or more structural or functional features of resonator 100A described with reference to FIG. 1. Accordingly, unless otherwise specified, the description of resonator 100A is equally applicable to resonator 100D. Lid 210D may incorporate one or more structural or functional features of lid 210B described with reference to FIG. 2A. Accordingly, unless otherwise specified, the description of lid 210B is equally applicable to lid 210D.

Resonator 100D may include oxide 226D, opening 248D, and trench 320D. Oxide 226 may be fabricated on substrate 110D. Opening 248D may provide access to silicon 126D, for example to reduce the mass of silicon 126D during fabrication. Various etch processes, such as wet chemical etching, reactive ion etching (RIE), deep reactive ion etching (DRIE), plasma etching, and/or vapor phase etching, may be employed to selectively remove material from silicon 126D to reduce its mass while preserving desired structural and functional integrity.

FIG. 2D shows a cross sectional view of a resonator in a chip-scale package (CSP) 200D, according to some embodiments. CSP 200D may include resonator 100E and lid 210E. Resonator 100E may incorporate one or more structural or functional features of resonator 100A described with reference to FIG. 1. Accordingly, unless otherwise specified, the description of resonator 100A is equally applicable to resonator 100E. Lid 210E may incorporate one or more structural or functional features of lid 210B described with reference to FIG. 2A. Accordingly, unless otherwise specified, the description of lid 210B is equally applicable to lid 210E.

Resonator 100D may include post 252E, opening 248D, trench 320D, hole 254E, and plug 256E. Hole 254 formed in silicon 224D may be used to introduce a vacuum into an internal cavity and/or to evacuate residual materials or byproducts remaining from earlier semiconductor processing steps. For example, various etch processes, such as wet chemical etching, reactive ion etching (RIE), deep reactive ion etching (DRIE), plasma etching, and/or vapor phase etching, may be employed to selectively remove material from silicon 126D to reduce its mass while preserving desired structural and functional integrity. Plug 256E may seal hole 254—such as after the introduction of vacuum to the cavity—using a localized energy application process, such as laser-assisted sealing, or alternatively by deposition of a plug material including silicon, glass, metal, or polymer, to restore hermeticity or isolate the cavity from the external environment. Post 252E may support a cantilever structure when the cantilevers are formed as a unitary body, and when the cantilevers are separated, post 252E may be positioned between two adjacent cantilevers.

### Wafer-Level Package

FIG. 2B shows a cross sectional view of a resonator in a wafer-level package 200B, in various embodiments. Wafer-level package 200B may include resonator 100C, lid 210C, overmold 242C, substrate 244C, and pad 246C-1. Resonator 100C may incorporate one or more structural or functional features of resonator 100A described with reference to FIG. 1. Accordingly, unless otherwise specified, the description of resonator 100A is equally applicable to resonator 100B. Lid 210C may incorporate one or more structural or functional features of lid 210B described with reference to FIG. 2A. Accordingly, unless otherwise specified, the description of lid 210B is equally applicable to lid 210C.

Overmold 242C may comprise a molding compound used in integrated circuit packaging, such as epoxy-based materials including epoxy novolac, bismaleimide triazine (BT) resin, phenolic resin, and/or silica-filled epoxy. Substrate 244C may comprise a printed circuit board (PCB) material such as FR-4, BT resin, polyimide, and/or ceramic. Pad 246C-1 and pad 246C-2 may be metal traces formed on substrate 244C and may include a solder material disposed thereon to facilitate electrical and mechanical connection to external components.

FIG. 4B illustrates a wafer-level package 200G, according to some embodiments. wafer-level package 200G may include pad 246T-1 and 246T-2, among others. Pad 246T-1 and 246T-2 may be structurally and/or functionally similar to pad 246C-1 and 246C-2 described with reference to FIG. 2B, and unless otherwise indicated, the description of pad 246C-1 and 246C-2 is considered applicable to pad 246T-1 and 246T-2. By way of example and not limitation, wafer-level package 200G may have dimensions 1.2 mm×1.0 mm×0.35 mm.

### Top

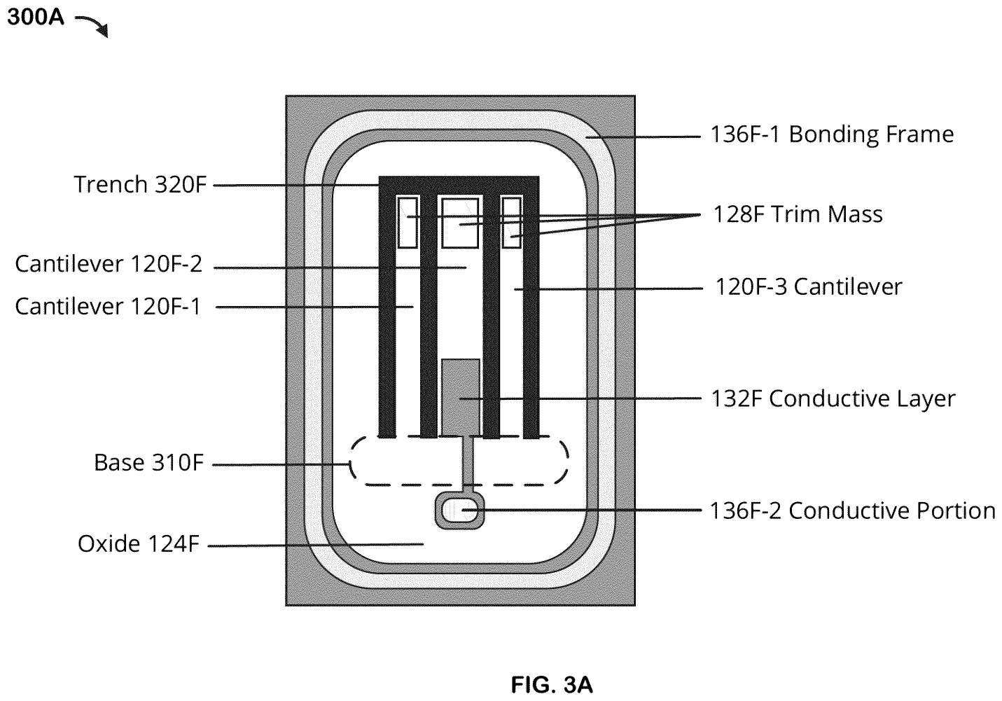

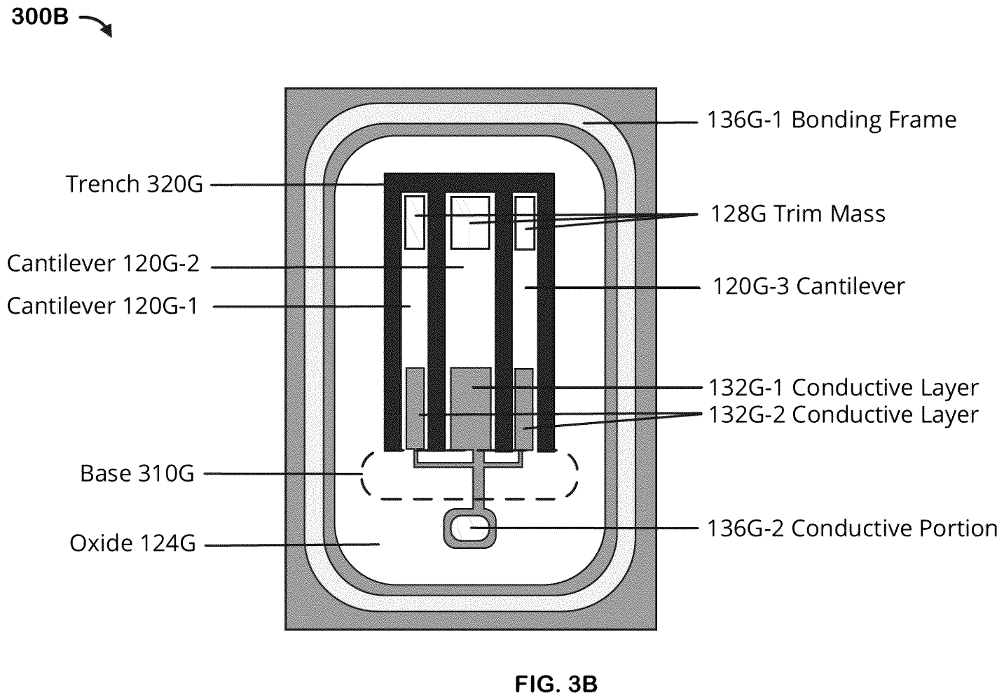

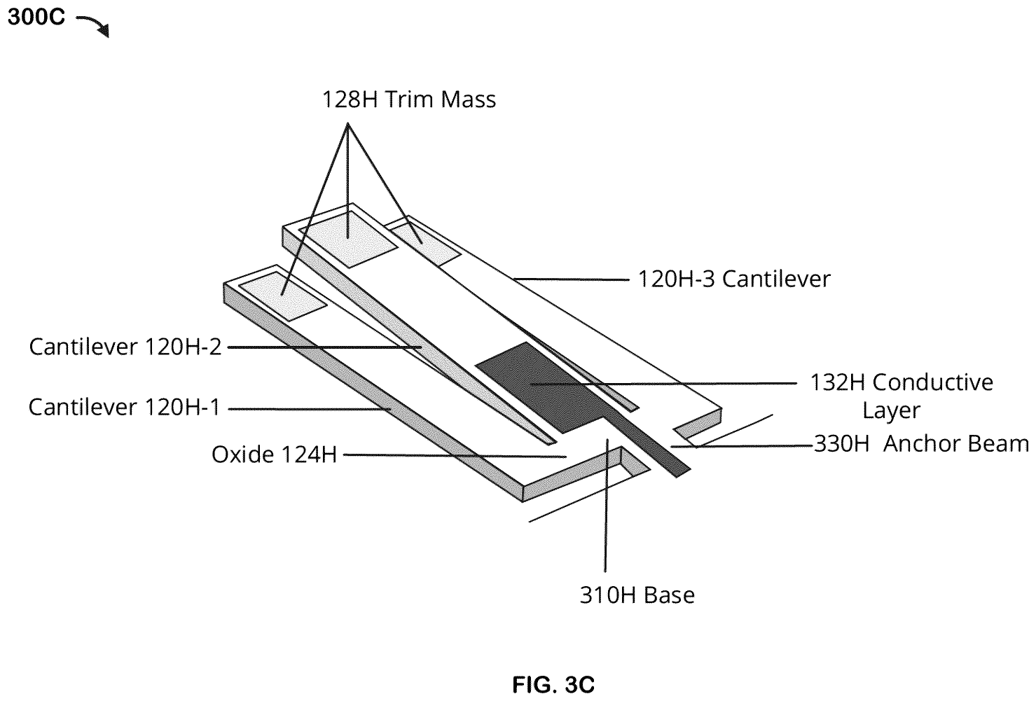

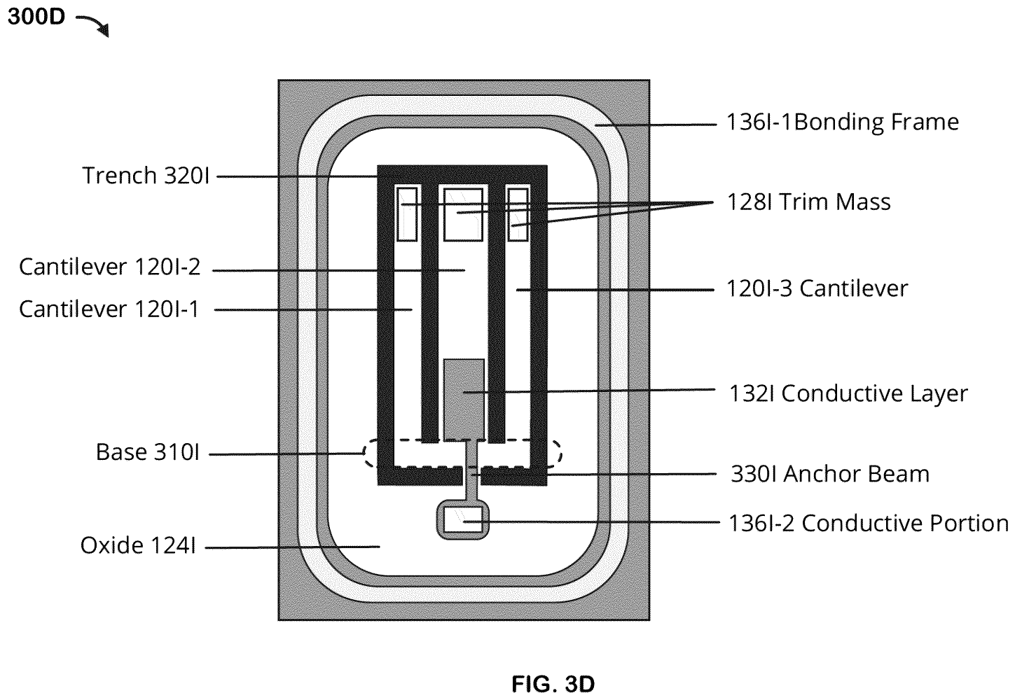

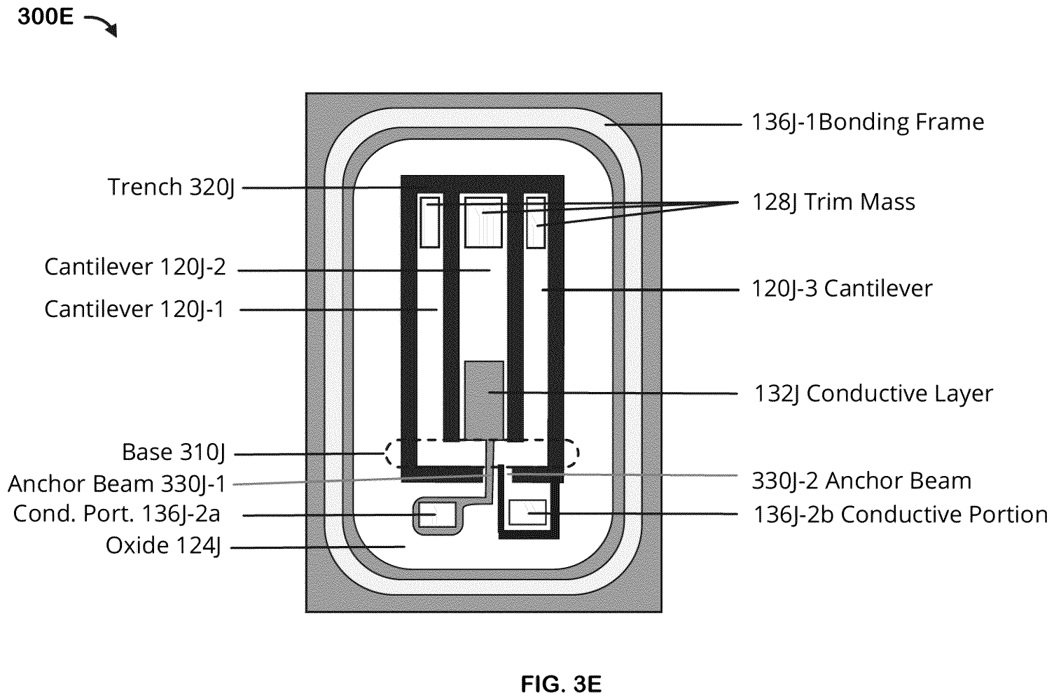

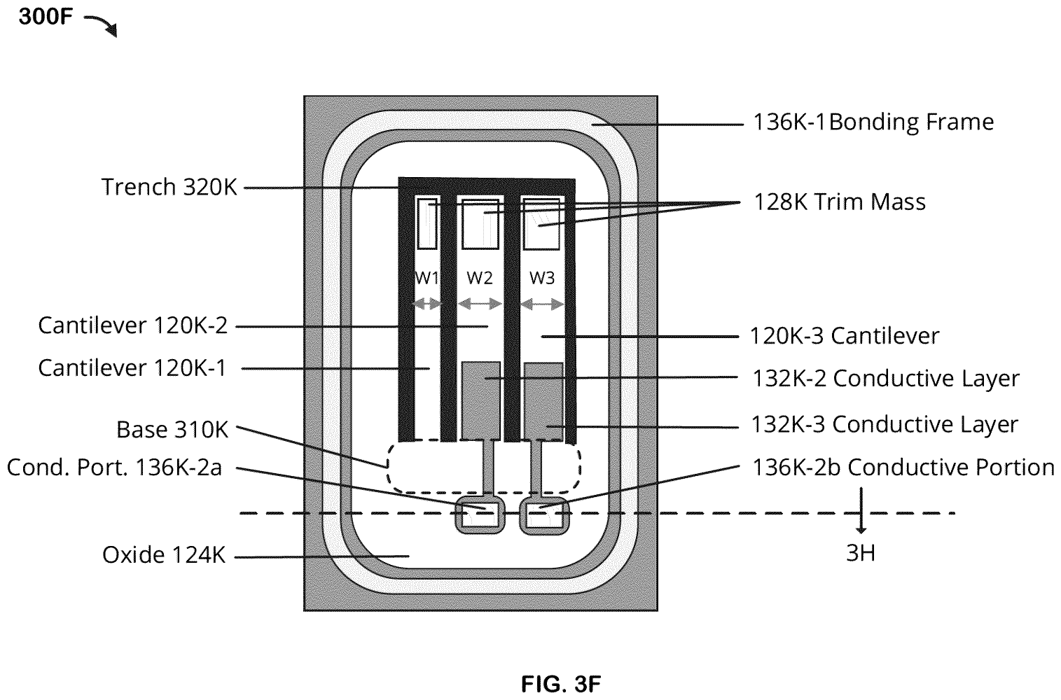

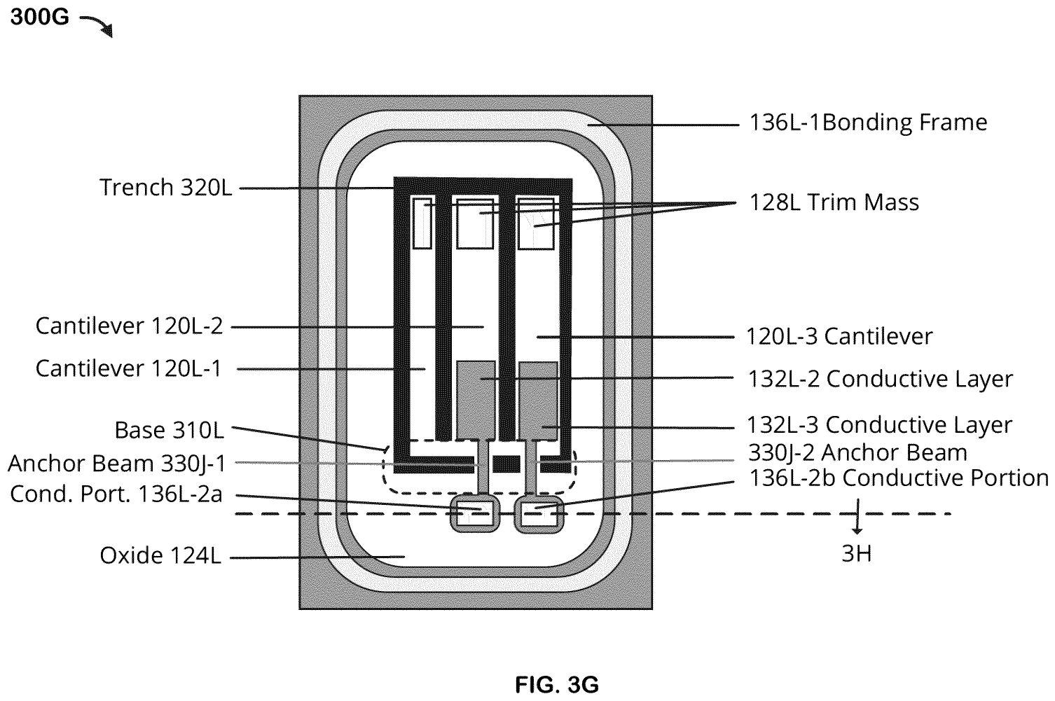

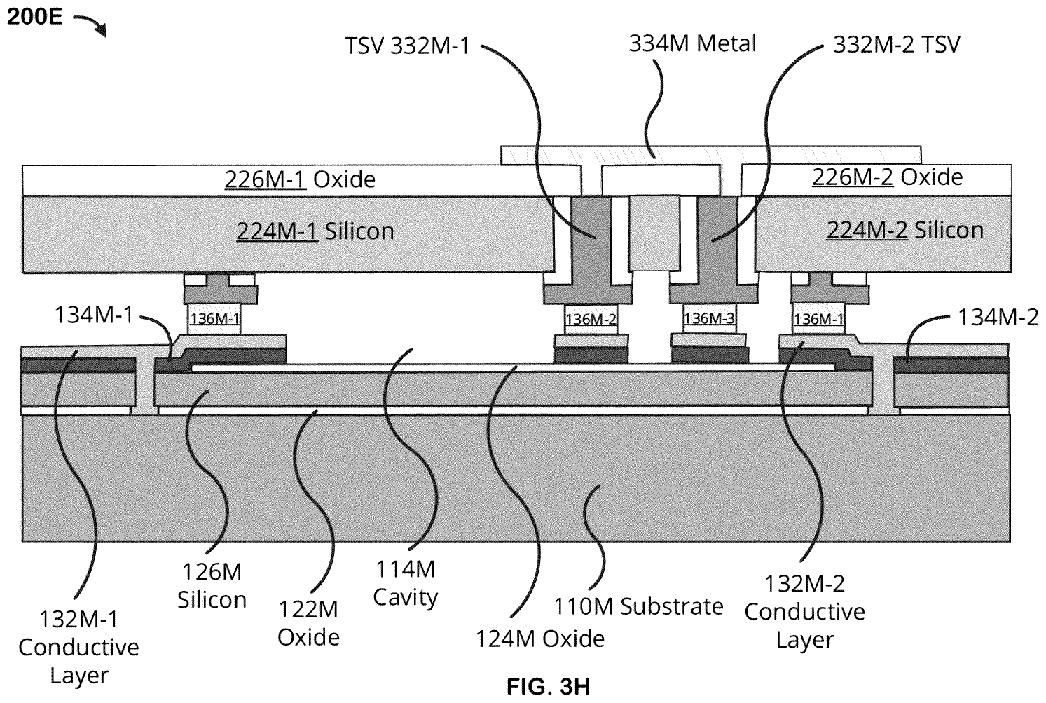

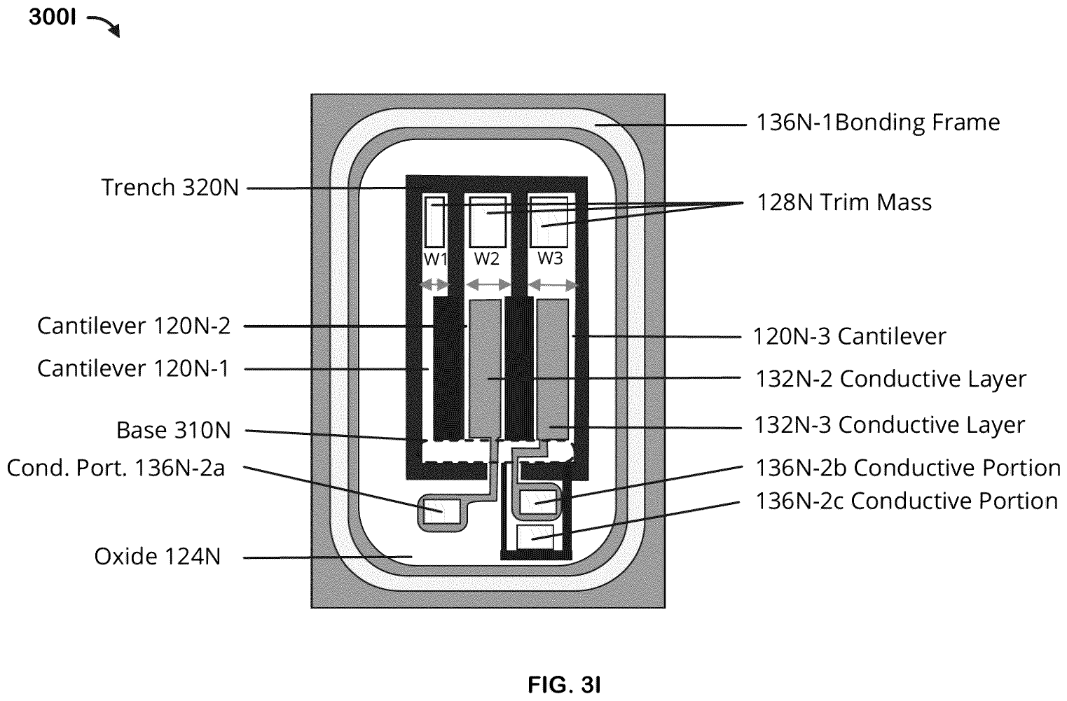

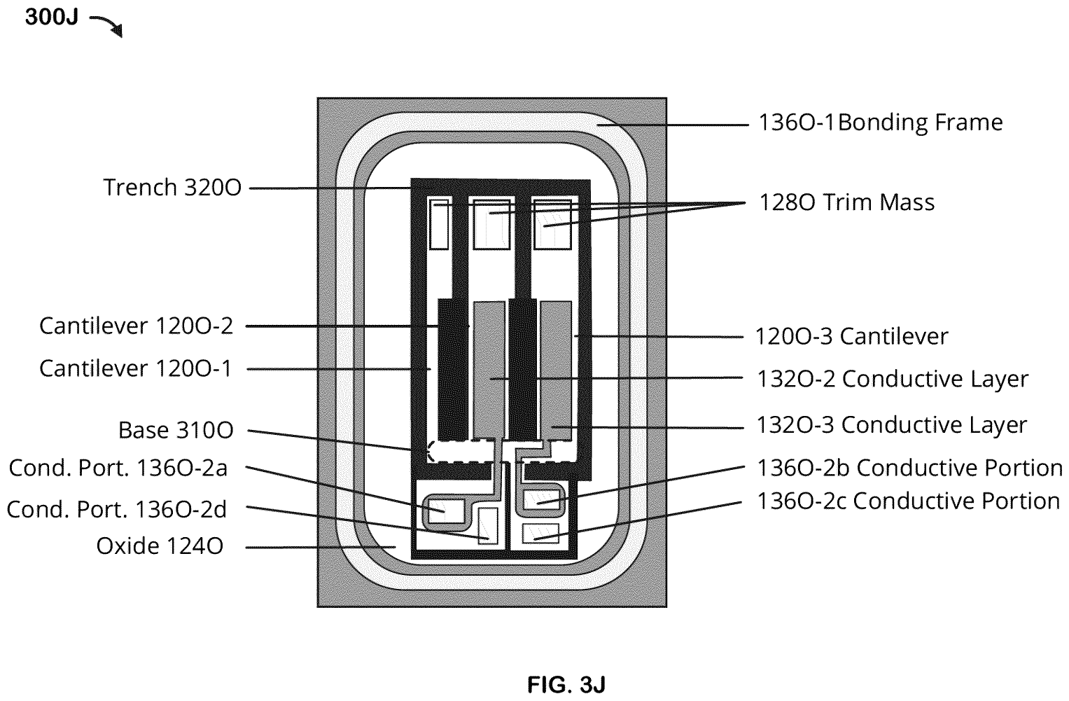

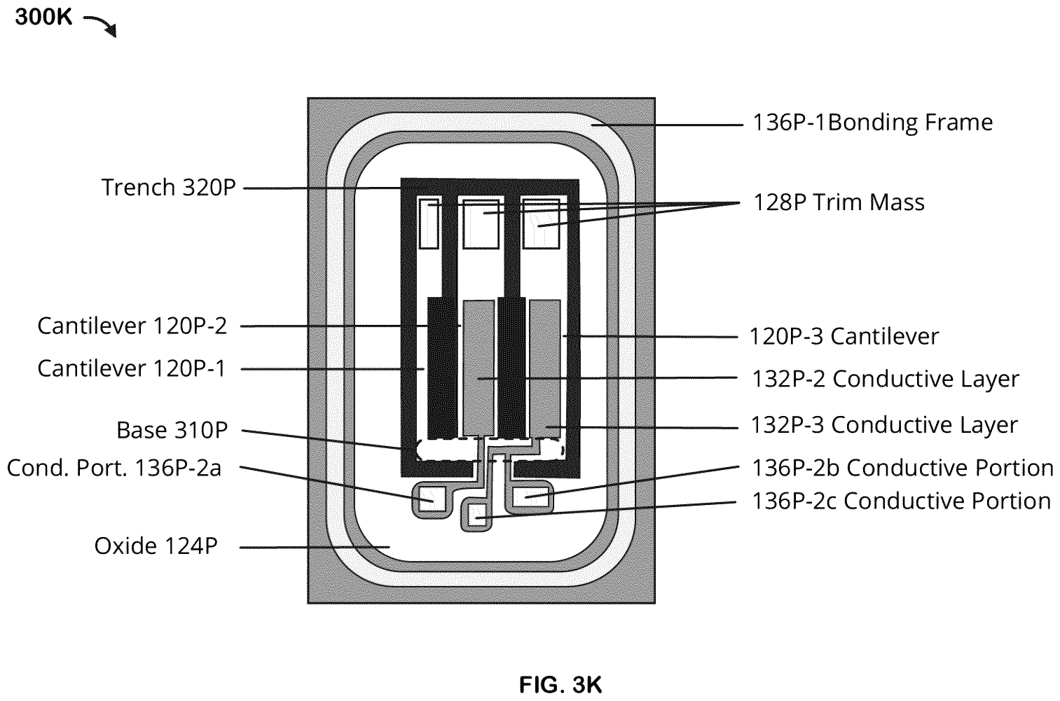

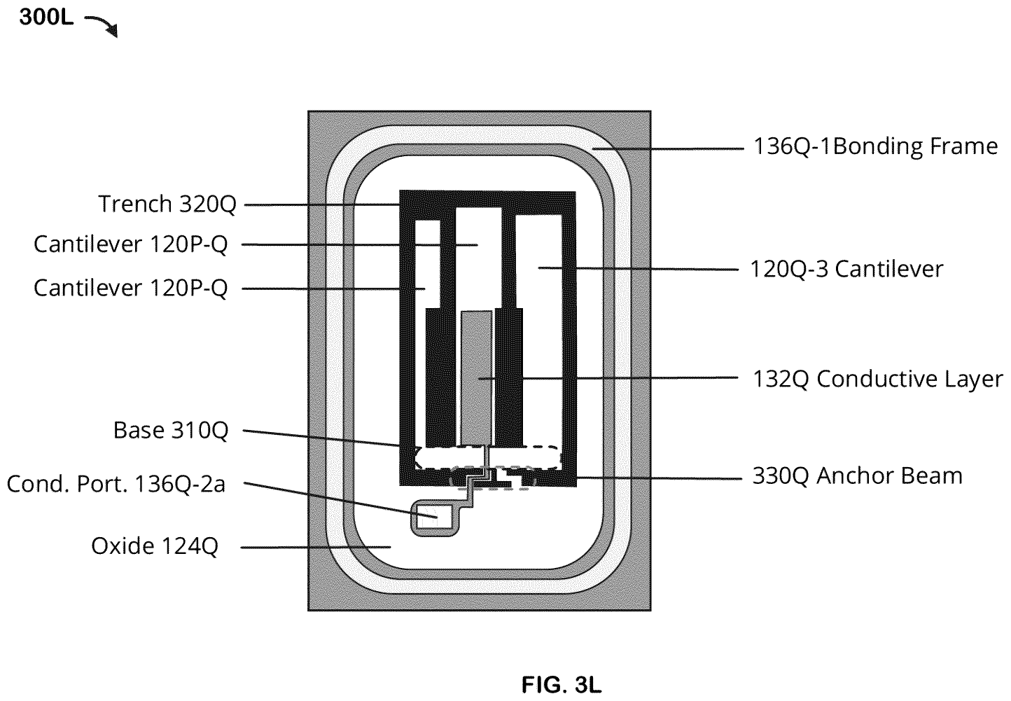

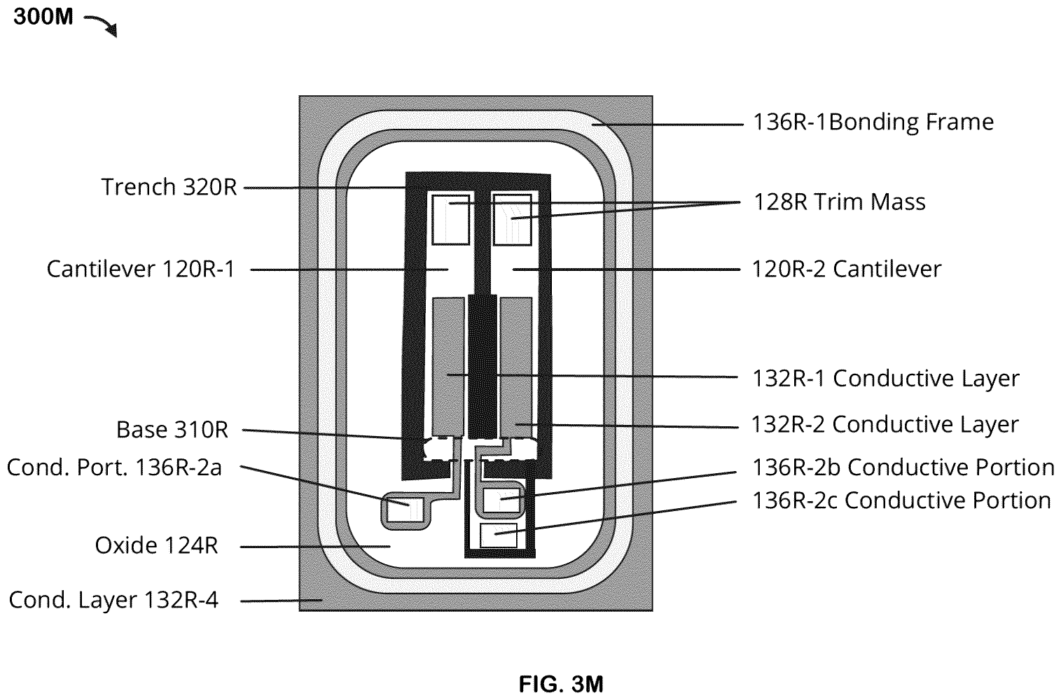

Unless otherwise specified, the structural and functional features described with reference to resonator 100A in FIG. 1 and resonators 200A-200D in FIGS. 2A-2D are equally applicable to resonators 300A through 300M in FIGS. 3A-3M without departing from the scope of the present disclosure. Moreover, elements described in relation to any one of FIGS. 3A-3M may be considered applicable to corresponding elements in the other figures.

FIG. 3A depicts a top view of resonator 300A including three cantilevers, according to various embodiments. Resonator 300A may include oxide 124F, base 310F, cantilever 120F-1-120F3, trench 320F, bonding frame 136F-1, trim mass 128F, conductive layer 132F, and conductive portion 136F2.

Base 310F may serve as a common junction at which cantilevers 120F-1-120F-3 are joined, providing structural support and mechanical continuity between the cantilever elements. Trench 410 may comprise a void, space, or cavity formed in the substrate or silicon body, within which one or more cantilevers are disposed and configured to resonate during operation. Bonding frame 136F-1 may comprise a conductive portion, such as conductive portion 136A-1 described with reference to FIG. 1, and may function as a seal ring or bonding frame configured to facilitate wafer bonding.

As shown, cantilever 120F-2 may be driven through conductive portion 136F-2. Cantilever 120F-1 and 120F3 may be configured to oscillate either in phase with cantilever 120F-2, wherein their motion is synchronized in direction and timing, or out of phase, wherein their motion occurs in opposite directions or with a phase offset, depending on the excitation conditions and structural coupling.

FIG. 3B depicts a top view of resonator 300B including three cantilevers, according to various embodiments. Resonator 300B may include oxide 124G, base 310G, cantilever 120G-1-120G-3, trench 320G, bonding frame 136G-1, trim mass 128G, conductive layer 132G-1 and 132G-2, and conductive portion 136G2.

Cantilevers 120G-1-120G-3 may include piezoelectric film (e.g., dielectric material layer 134A-2 in FIG. 1) beneath the conductive on the outside cantilevers 120G-1 and 120G-3 having the opposite polarity from the piezoelectric film on the center cantilever. Here, the out-of-phase motion may generate a charge with the same polarity on all electrodes and the electrodes may be connected together at conductive portion 136G-2.

The outer cantilevers may be selectively connected electrically together and selectively isolated electrically from the center cantilever (not shown in FIG. 2C). The outer cantilevers and center cantilever may be subsequently electrically connected.

FIG. 3C illustrates cantilever motion of resonator 300C, where the outer cantilevers 120H1-1 and 120H-3 move out of phase with respect to the center cantilever 120H-2, in some embodiments.

FIG. 3D depicts a top view of a resonator 300D having an extended trench 3201 around base 310I, in accordance with various embodiments. Extended trench 310I may advantageously reduce changes in resonance frequency due to environmental stress, such as package stress.

FIG. 3E depicts a top view of a resonator 300E having conductive portion 136J-2b (e.g., another electrode) to the structural silicon that allows heating of the resonator structure, in various embodiments. When current is passed through conductive portion 136J-2b to conductive portion 136J-2a, the current will flow through the resonator resulting in resistive heating. The use of two separate electrical contacts (conductive portion 136J-2a and 136J-2b) enables independent measurement of voltage and/or current, which may be utilized, for example, to verify electrical connectivity or to pass current through the contacts for heating the resonator to a desired temperature. It is understood that alternative configurations are contemplated, including implementations in which both contacts are coupled to transducers in cantilever 120J-2, to both left and right transducers in cantilevers 120J-1 and 120J-3, or to a single transducer having dual contact points. For example, heating may be used to change a characteristic(s) of the resonator, such as its resonant frequency. Thermal trimming is discussed in U.S. Pat. No. 9,712,128 titled “Microelectromechanical Resonator” and U.S. Pat. No. 10,218,333 titled “Microelectromechanical Resonator,” each of which is incorporated by reference herein. Moreover, the use of two separate electrical contacts enables independent measurement of voltage and/or current, which may be utilized, for example, to verify electrical connectivity/

What is claimed is:

1. A micro-electromechanical systems (MEMS) resonator comprising:
a substrate;
a base coupled to the substrate;
a first cantilever coupled to the base, the first cantilever comprising:
a silicon layer,
an insulating layer disposed on the silicon layer, and
a piezoelectric layer disposed on the insulating layer and selectively coupled to the silicon layer through at least one opening in the insulating layer;
a second cantilever and a third cantilever each coupled to the base;
a first electrode coupled to the piezoelectric layer; and
a second electrode coupled to the substrate.
